(19) United States
(12) Patent Application Publication
(10) Pub. No.: US 2009/0253272 A1
(43) Pub. Date: Oct. 8, 2009

(54) Method for manufacturing semiconductor device and substrate processing apparatus

(75) Inventor: Tadashi Terasaki, Imizu-shi (JP)

Correspondence Address: OLIFF & BERRIDGE, PLC, P.O. BOX 320850, ALEXANDRIA, VA, 22320-4850, US

(73) Assignee: HITACHI KOKUSAI ELECTRIC INC., Tokyo (JP)

(21) Appl. No.: 12/382,983

(22) Filed: Mar. 27, 2009

(30) Foreign Application Priority Data
Apr. 7, 2008 (JP) 2008-099351
Dec. 22, 2008 (JP) 2008-325576
Mar. 17, 2009 (JP) 2009-63802

(51) Int. Cl. H01L 21/316; C23C 16/513

(52) U.S. Cl. 438/786; 118/723 R; 257/E21.279

(57) ABSTRACT

A gate insulating film with less leakage current is formed, while a surface temperature of a silicon substrate is decreased. Gas containing oxygen atoms and nitrogen atoms is supplied into a processing chamber, then the gas containing the oxygen atoms and the nitrogen atoms is activated by plasma, and the silicon substrate is subjected to processing by plasma, and a silicon dioxide film containing nitrogen is formed.

### BACKGROUND

1. Technical Field

The present invention relates to a method for manufacturing a semiconductor device for processing a substrate by using plasma, and a substrate processing apparatus.

2. Description of Related Art

Silicon dioxide (SiO₂) is mainly used as a material of a tunnel layer provided in a semiconductor logic device and a DRAM device, etc, or a tunnel layer provided in a flush memory. Such a tunnel layer is formed by heating a surface of a silicon (Si) substrate, in which a source region and a drain region are previously formed, so as to be a temperature of 900° C. or more, and by exposing the surface of a heated silicon substrate to gas containing oxygen atoms. Note that in order to further reduce a leakage current, hydrogen atoms are mixed into the gas to which the surface of the silicon substrate is exposed, and an unstable level in the tunnel layer is terminated by hydrogen (H) atoms (dangling bonds are recombined) in some cases.

However, when the surface temperature of the silicon substrate is heated up to 900° C. or more, diffusion occurs in the source region and the drain region formed in the silicon substrate, thus degrading circuit characteristics and deteriorating a performance of a semiconductor device in some cases. In addition, by adding a long-term electrical stress to the tunnel layer, hydrogen atoms are desorbed from the tunnel layer, to allow gradual increase of the leakage current of the tunnel layer to occur, resulting in reduction in reliability of the tunnel layer in some cases.

Therefore, an object of the present invention is to provide a method for manufacturing the semiconductor device and a substrate processing apparatus capable of forming the tunnel layer with less leakage current, while decreasing the surface temperature of the silicon substrate.

### SUMMARY OF THE INVENTION

According to a first aspect of the present invention, there is provided a method for manufacturing a semiconductor device including the steps of: supplying gas containing oxygen atoms and nitrogen atoms into a processing chamber; activating the gas containing the oxygen atoms and the nitrogen atoms by plasma; and forming a silicon dioxide film containing nitrogen by applying processing to the a silicon substrate by the plasma.

According to the method for manufacturing the semiconductor device of the present invention, the tunnel layer with less leakage current can be formed, while decreasing a surface temperature of the silicon substrate.

### BRIEF DESCRIPTION OF THE DRAWINGS

FIG. 1 is a graph illustrating a depth profile (composition analysis result in a thickness direction) of a tunnel layer.

FIG. 2 is a graph illustrating the depth profile (composition analysis result in a thickness direction) of the tunnel layer when the ratio of a supply flow rate of O₂ gas to the supply flow rate of N₂ gas is changed.

FIG. 3 is a graph for comparing a measured value of a leakage current of the tunnel layer and a measured value of the leakage current of the tunnel layer formed by other method according to this embodiment.

FIG. 4 is a sectional block diagram of an MMT apparatus, being a semiconductor manufacturing apparatus for executing a method for manufacturing a semiconductor device according to this embodiment.

FIG. 5 is a sectional block diagram of a charge trap type flush memory.

FIG. 6 is a sectional block diagram of an ICP plasma processing apparatus, being the semiconductor manufacturing apparatus, for executing the method for manufacturing the semiconductor device according to this embodiment.

FIG. 7 is a sectional block diagram of an ECR plasma processing apparatus, being the semiconductor manufacturing apparatus, for executing the method for manufacturing the semiconductor device according to this embodiment.

### DESCRIPTION OF PREFERRED EMBODIMENTS OF THE INVENTION

As described above, when the surface temperature of the silicon substrate is heated up to 900° C. or more, diffusion occurs in a source region and a drain region formed in the silicon substrate, thus degrading circuit characteristics and deteriorating the performance of the semiconductor device in some cases. In addition, by adding a long-term electrical stress to the tunnel layer, hydrogen atoms are desorbed from the tunnel layer, to allow gradual increase of the leakage current of the tunnel layer to occur, resulting in the reduction in reliability of the tunnel layer in some cases.

Therefore, an inventor of the present invention makes strenuous efforts aimed at achieving a method for forming the tunnel layer with less leakage current. As a result, the inventor of the present invention obtains the knowledge that the aforementioned problems can be solved by activating the gas containing oxygen atoms by plasma, and exposing the surface of the silicon substrate to the activated gas. Also, the inventor of the present invention obtains the knowledge that the reliability of the tunnel layer can be increased by containing nitrogen atoms in the gas. The present invention is provided based on the knowledge obtained by the inventor of the present invention as described above. An embodiment of the present invention will be described hereunder.

### (1) Structure of a Semiconductor Manufacturing Apparatus

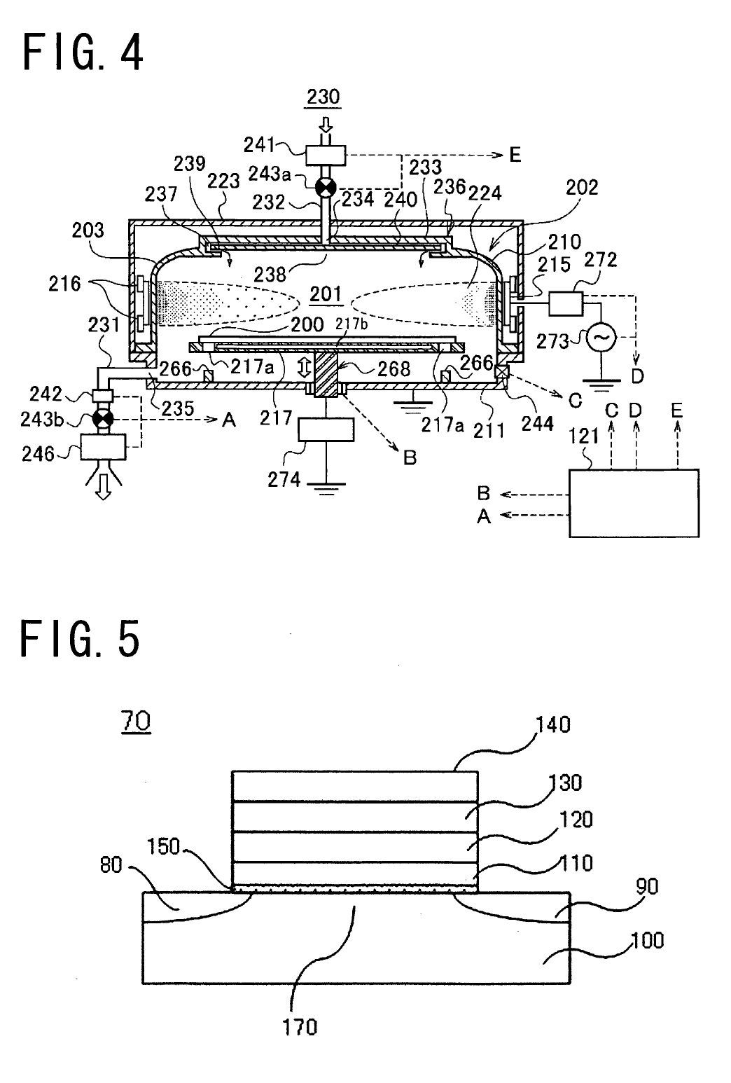

First, a constitutional example of a semiconductor manufacturing apparatus that executes a method for manufacturing the semiconductor device according to this embodiment will be described by using FIG. 4. FIG. 4 is a sectional block diagram of an MMT apparatus, being the semiconductor manufacturing apparatus. The MMT apparatus is a device for applying plasma processing to a silicon substrate 100 such as a silicon wafer, by using a modified magnetron typed plasma source capable of generating high-density plasma by an electric field and a magnetic field.

The MMT apparatus includes a processing furnace 202 for applying plasma processing to the silicon substrate 100. In addition, a processing furnace 202 includes a processing vessel 203 for constituting a processing chamber 201; a susceptor 217; a gate valve 244; a shower head 236; a gas exhaust port 235; a plasma generator (cylindrical electrode 215, upper magnet 216a, lower magnet 216b); and a controller 121.

As shown in FIG. 4, the processing vessel 203 provided in the processing chamber 201 includes a dome-shaped upper side vessel 210, being a first vessel, and a bowl-shaped lower side vessel 211, being a second vessel. Then, the processing chamber 201 is formed by overlaying the upper side vessel 210 on the lower side vessel 211. Note that the upper side vessel 210 is formed of a non-metal material such as aluminum oxide or quartz, and the lower side vessel 211 is formed of aluminum.

The susceptor 217, being a substrate holder for holding the silicon substrate 100 is disposed in a bottom side center in the processing chamber 201. The susceptor 217 is formed of a non-metal material such as aluminum nitride, ceramics, or quartz, so that metal contamination of a film formed on the silicon substrate 100 can be reduced.

A heater 217b, being a heating unit, is integrally embedded in the susceptor 217, so that the silicon substrate 100 can be heated. When electric power is supplied to the heater, the surface of the silicon substrate 100 can be heated up to about 600° C. to 900° C.

The susceptor 217 is electrically insulated from the lower side vessel 211. A second electrode (not shown), being an electrode for changing an impedance, is installed inside of the susceptor 217. This second electrode is grounded through an impedance variable unit 274. The impedance variable unit 274 is constituted of a coil and a variable capacitor, and by controlling the number of patterns of the coil and a capacitor value of the variable capacitor, a potential of the silicon substrate 100 can be controlled through the second electrode (not shown) and the susceptor 217.

A susceptor elevation unit 268 for elevating the susceptor 217 is provided in the susceptor 217. Through holes 217a are provided in the susceptor 217. Wafer lifting pins 266 for lifting the silicon substrate 100 are provided in at least three places on a bottom face of the lower side vessel 211. Then, the through holes 217a and the wafer lifting pins 266 are mutually arranged, so that the wafer lifting pins 266 are passed through the through holes 217a in a non-contact state between the wafer lifting pins 266 and the susceptor 217, when the susceptor 217 is descended by the susceptor elevation unit 268.

A gate valve 244, being a partition valve, is provided on a side wall of the lower side vessel 211. When the gate valve 244 is opened, the silicon substrate 100 can be loaded into the processing chamber 201 by using a carrying means (not shown), or the silicon substrate 100 can be unloaded to outside the processing chamber 201. By closing the gate valve 244, the inside of the processing chamber 201 can be air-tightly closed.

A shower head 236 for supplying gas into the processing chamber 201 is provided in an upper part of the processing chamber 201. The shower head 236 includes a cap-shaped lid member 233; a gas inlet port 234; a buffer chamber 237; an opening 238; a shielding plate 240; and a gas outlet port 239.

A gas supply tube 232 for supplying gas into the buffer chamber 237 is connected to the gas inlet port 234. The buffer chamber 237 functions as a dispersion space for dispersing a reaction gas 230 introduced from the gas inlet port 234.

Note that the gas supply tube 232 is connected to an O₂ gas cylinder (not shown) for supplying oxygen (O₂) gas, being an oxygen content gas (reaction gas), and a N₂ gas cylinder (not shown) for supplying nitrogen (N₂), being a nitrogen content gas (reaction gas), through a valve 243a, being an open/close valve, and a mass flow controller 241, being a flow rate controller, respectively. The O₂ gas cylinder and the N₂ gas cylinder include valves (not shown), being open/close valves respectively. By opening/closing these valves (not shown) and the valve 243a, the O₂ gas and the N₂ gas, being the reaction gas, can be freely supplied into the processing chamber 201 as the reaction gas, through the gas supply tube 232.

A gas exhaust port 235 for exhausting the gas from the processing chamber 201 is provided on a side wall of the lower side vessel 211. A gas exhaust tube 231 for exhausting the gas is connected to the gas exhaust port 235. The gas exhaust tube 231 is connected to a vacuum pump 246, being an exhaust device, through an APC 242, being a pressure adjuster, and a valve 243b, being an open/close valve.

The cylindrical electrode 215, being the first electrode, is provided on an outer periphery of the processing vessel 203 (upper side vessel 210) so as to surround a plasma generating region in the processing chamber 201. The cylindrical electrode 215 is formed into a cylinder shape, such as a columnar shape. The cylindrical electrode 215 is connected to a high frequency electrical power source 273 for applying high frequency electrical power, through a matching unit 272 for performing impedance matching. The cylindrical electrode 215 functions as a discharging unit whereby the O₂ gas and the N₂ gas supplied into the processing chamber 201 are excited by plasma.

An upper magnet 216a and a lower magnet 216b are respectively attached to upper/lower end portions on an outer surface of the cylindrical electrode 215. The upper magnet 216a and the lower magnet 216b are respectively constituted as permanent magnets formed, for example, into a ring shape.

The upper magnet 216a and the lower magnet 216b have magnetic poles at both ends (namely inner peripheral end and outer peripheral end) along a radius direction of the processing chamber 201. Directions of the magnetic poles of the upper magnet 216a and the lower magnet 216b are arranged in a direction opposite to each other. Namely, the magnetic poles of the inner peripheral parts of the upper magnet 216a and the lower magnet 216b are set as different poles. Thus, a magnetic line in a cylindrical axis direction is formed along an inner surface of the cylindrical electrode 215.

After introducing the O₂ gas and the N₂ gas into the processing chamber 201, an electric field is formed by supplying high frequency electric power to the cylindrical electrode 215, and also a magnetic field is formed by using the upper magnet 216a and the lower magnet 216b, and magnetron discharge plasma is thereby generated in the processing chamber 201. At this time, by giving circulating motion of emitted electrons by the aforementioned electromagnetic field, ionization rate of plasma is increased and the plasma with long life and high density can be generated.

Note that a shielding plate 223 made of metal for effectively shielding the electromagnetic field is provided around the cylindrical electrode 215, the upper magnet 216a, and the lower magnet 216b, so that the electromagnetic field formed thereby has no adverse influence on an outside environment and other device such as a processing furnace.

In addition, the controller 121, being a control unit, controls the APC 242, the valve 243b, and the vacuum pump 246 through a signal line A, controls the susceptor elevation unit 268 thorough a signal line B, controls the gate valve 244 through a signal line C, controls the matching unit 272 and the high frequency power source 273 through a signal line D, controls the mass flow controller 241 and the valve 243a through a signal line E, and controls the heater embedded in the susceptor and the impedance variable unit 274 through a signal line not shown, respectively.

### (2) Method for Manufacturing a Semiconductor Device

First, prior to explanation for the method for manufacturing the semiconductor device according to this embodiment, a structure of a charge trap flash memory will be described as an example of the semiconductor device manufactured by this method. FIG. 5 is a sectional block diagram of the charge trap flash memory.

As shown in FIG. 5, a charge trap flash memory 70 includes the silicon substrate 100 in which a source region 80, a drain region 90, and a channel layer 170 are formed. A tunnel layer (silicon dioxide SiO₂) 110 is formed on the silicon substrate 100 so as to straddle the source region 80 and the drain region 90. A charge conservation layer 120 made of silicon nitride (SiN) is formed on the tunnel layer 110. An insulating film 130 is formed on the charge conservation layer 120. A gate electrode layer 140 is formed on the insulating layer 130.

A nitridation layer is formed in an interface between the tunnel layer 110 and the silicon substrate 110. This nitridation layer 150 has a function of restraining the leakage current from a tunnel oxide layer 120. The charge passes through the tunnel layer 110, and is stored in a trap site of the aforementioned charge conservation layer 120. A method for manufacturing each layer will be described later.

Subsequently, the method for manufacturing the semiconductor device according to this embodiment will be described. A silicon dioxide (SiO₂) film 110, being the tunnel layer 110, is formed on the silicon substrate 100. At this time, the nitridation layer 150 is formed in the interface between the tunnel layer 110 and the silicon substrate 100. The step of forming the tunnel layer 110 and the nitridation layer 150 will be described later in detail.

After forming the tunnel layer 110, the charge conservation layer 120 (SiN) is formed, and the insulating layer 130, being an insulating film, is further formed thereon. Next, the gate electrode layer 140 is formed on the insulating layer 130. After each layer is deposited, both sides of the gate electrode layer are etched by etching processing, to expose an upper part of the silicon substrate 100. Impurities are implanted into the circumference of the gate electrode layer in the exposed silicon substrate, and the source region 80 and the drain region 90 are formed.

Next, the step of forming the tunnel layer 120 and the nitridation layer 150 in the method for manufacturing the semiconductor device according to this embodiment will be described. Such a manufacturing method is executed by the aforementioned MMT apparatus. Note that in the explanation given hereunder, an operation of each part constituting the MMT apparatus is controlled by the controller 121.

### (Loading of the Silicon Substrate)

First, the susceptor 217 is descended down to a carrying position of the silicon substrate 100, and the wafer lifting pins 266 are passed through the through holes 217a of the susceptor 217. As a result, the lifting pins 266 are set in a state of protruding by a specific height from the surface of the susceptor 217. Next, the gate valve 244 is opened, and by using the carrying means not shown, the silicon substrate 100 is supported on the wafer lifting pins 266 protruded from the surface of the susceptor 217. Subsequently, the carrying means is retreated to outside the processing chamber 201, and the gate valve 244 is closed to air-tightly close the processing chamber 201. Then, the susceptor 217 is elevated by using the susceptor elevation unit 268. As a result, the silicon substrate 100 is disposed on an upper surface of the susceptor 217. Thereafter, the silicon substrate 100 is elevated up to its processing position.

### (Heating of the Silicon Substrate)

Subsequently, electric power is supplied to the heater 217b embedded in the susceptor, to heat the surface of the silicon substrate 100. A surface temperature of the silicon substrate 100 is preferably set at 600° C. or more and under 900° C., and more preferably set at 675° C. or more and 800° C. or less.

In the heat treatment of the silicon substrate 100, when the surface is heated up to temperature of 900° C. or more, diffusion occurs in the source region 80 and the drain region 90 formed in the silicon substrate, thus degrading the circuit characteristics and deteriorating the performance of the semiconductor device in some cases. In addition, by adding a long-term electrical stress to the tunnel layer 110, the hydrogen atoms are desorbed from the tunnel layer, and the leakage current of the tunnel layer 110 is gradually increased, resulting in the reduction in reliability of the tunnel layer 110 in some cases. The diffusion of the impurities in the source region 80 and the drain region 90 formed in the silicon substrate 100, the degradation of the circuit characteristics, and the deterioration of the performance of the semiconductor device can be restrained by limiting the temperature of the silicon substrate 100 as described above. In the description hereunder, the surface temperature of the silicon substrate 100 is set at, for example, 700° C.

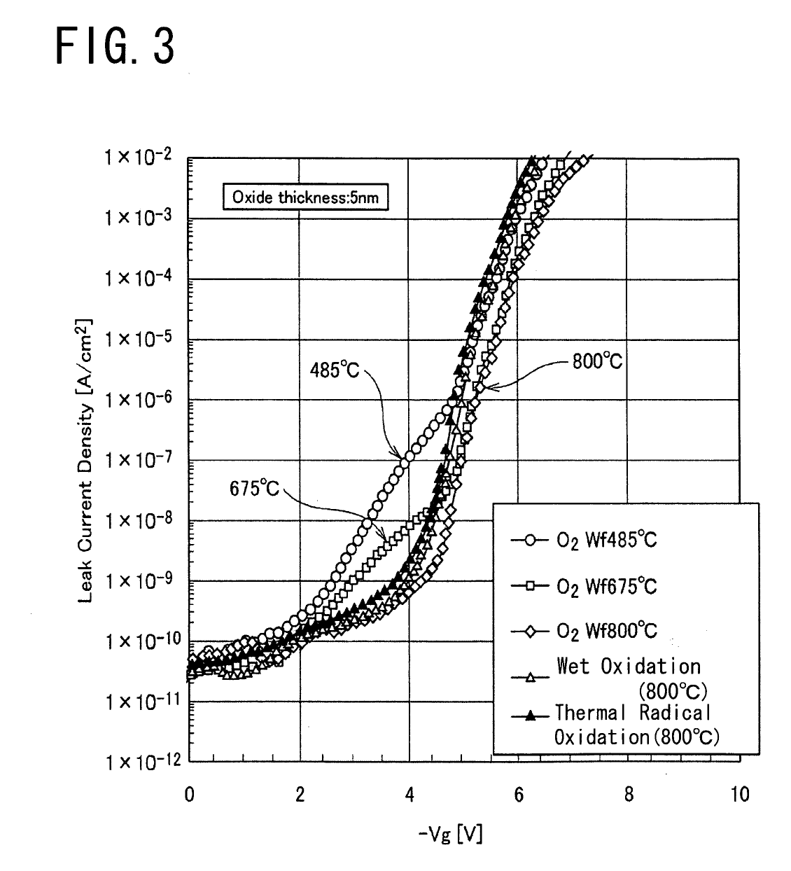

FIG. 3 is a view illustrating a result of comparison of temperature dependency of the leakage current between a plasma oxidation film (tunnel layer 120), and a thermal radical oxidation film and a Wet oxidation film. For example, when the axis where the voltage value is 4V is observed, it is found that the leakage current is 1×10⁻⁷ A/cm² at 485° C., while the leakage current is 1×10⁻⁸ A/cm² at 675° C. and a less leakage current is shown at this point. Also, a reference value of the leakage current of the tunnel insulating film for retaining the charge stored in the charge conservation layer at the time of forming the device is required to be 1×10⁻⁸ A/cm² at the voltage value of 4V, for example. Therefore, in order to realize this value, the temperature is preferably set at 650° C. or more.

### (Introduction of the O₂ Gas and the N₂ Gas)

Subsequently, the O₂ gas is introduced into the processing chamber 201 in a shower shape from the gas outlet port 234a. Also, at this time, preferably the N₂ gas is also introduced into the processing chamber 201 in a shower shape from the gas outlet port 234a. Although the tunnel layer 110 composed of SiO₂ can be formed by supplying only the O₂ gas, as will be described later, the nitrogen (N) atoms can be doped into a prescribed depth of the tunnel layer 110 composed of SiO₂, at a concentration of several %, by supplying the mixed gas of the O₂ gas and the N₂ gas into the processing chamber 201. When the tunnel layer 110 is thus doped with the nitrogen (N) atoms, strain of the interface between the silicon substrate 100 and the tunnel layer 110 is alleviated, and the tunnel layer 110 is strengthened against the electrical stress. In the description hereunder, the mixed gas of the O₂ gas and the N₂ gas is supplied into the processing chamber 201, with a supply flow rate of the O₂ gas set at 250 sccm, and the supply flow rate of the N₂ gas set at 250 sccm.

After the mixed gas of the O₂ gas and the N₂ gas is introduced, a pressure in the processing chamber 201 is adjusted so as to be set in a range of 0.1 to 300 Pa, such as 50 Pa, by using the vacuum pump 246 and the APC 242.

### (Plasmatization of the O₂ Gas and the N₂ Gas)

After the mixed gas of the O₂ gas and the N₂ gas is introduced, magnetron discharge is generated in the processing chamber 201, by applying high frequency electric power to the cylindrical electrode 215 from the high frequency electric power source 273 through the matching unit 272, and also by applying a magnetic force caused by the upper magnet 216a and the lower magnet 216b to the inside of the processing chamber 201. As a result, high density plasma is generated in a plasma generating region on the silicon substrate 100. Note that the electric power applied to the cylindrical electrode 215 is set, for example, in a range of about 100 to 500 W, such as 350 W. The impedance variable unit 274 at this time controls an impedance value to be a desired value in advance.

### (Formation of the Tunnel Layer)

By Plasmatization of the O₂ gas and the N₂ gas as described above, the O₂ gas and the N₂ gas supplied into the processing chamber 201 are activated. Then, the activated O₂ gas and N₂ gas are reacted with the surface of the silicon substrate 100, and the tunnel layer 110 composed of SiO₂ is formed on the silicon substrate 100, and also the tunnel layer 110 is set in a state of being doped with the nitrogen (N) atoms. The doped layer corresponds to the nitridation layer 150.

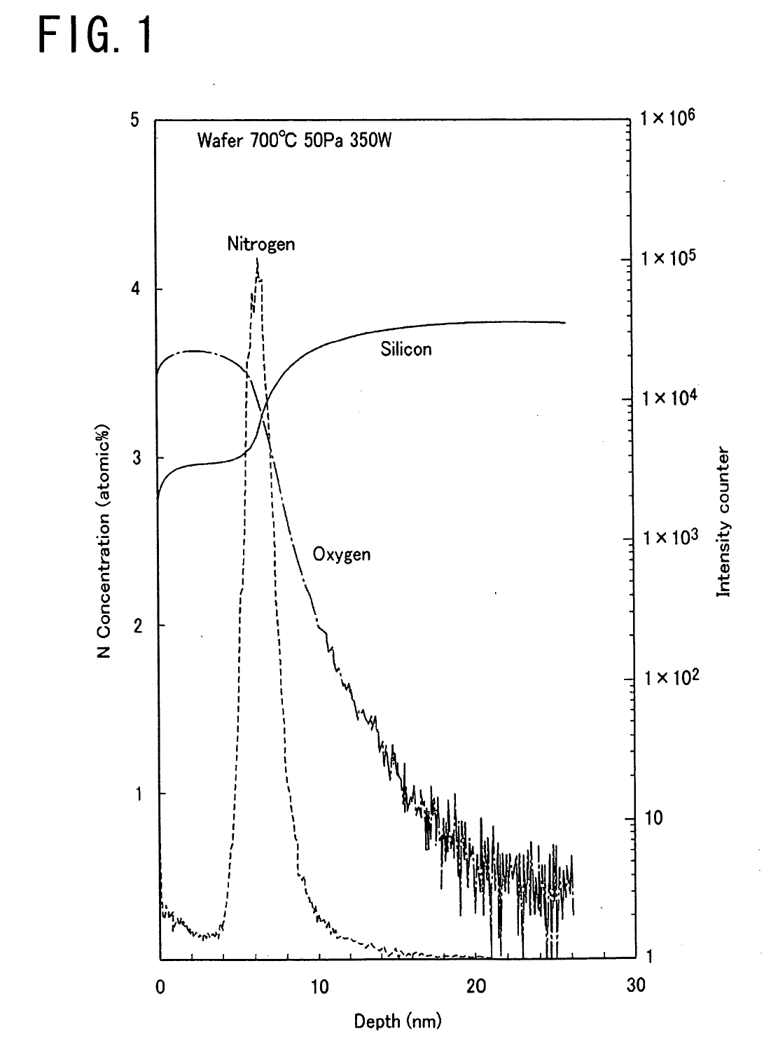

FIG. 1 illustrates a depth profile (composition analysis result in a thickness direction) of the tunnel layer 110 observed by SIMS (Secondary Ion Mass Spectrometry). In the figure, the tunnel layer 110 is formed based on the aforementioned conditions (namely, the surface temperature of the silicon substrate 100 set at 700° C., the supply flowrate of the O₂ gas set at 250 sccm, the supply flow rate of the N₂ gas set at 250 sccm, the pressure in the processing chamber 201 set at 40 Pa, and the high frequency electric power applied to the cylindrical electrode 215 set at 350 W). In the figure, the depth from the surface of the tunnel layer is indicated on the horizontal axis, and quantity of measurement (number of atoms) of the Si atoms and the o atoms is indicated by logarithm on the vertical axis at the right side of the figure, and the ratio (%) of the number of atoms of the measured N elements to the measured total numbers of atoms is indicated on the vertical axis at the left side of the figure. According to FIG. 1, it is found that the nitrogen (N) atoms are doped into a prescribe depth of the tunnel layer 110 (in the vicinity of 6 nm from the surface of the tunnel layer 110), so that the nitrogen atoms are unevenly distributed (in a maximum concentration of about 4%). When the tunnel layer 110 is thus doped, bonding degree between the silicon substrate 100 and the oxidation film is strengthened, to alleviate the strain of the interface between the silicon substrate 100 and the tunnel layer 110, and the tunnel layer 110 is strengthened against the electrical stress. Note that doses of N in the tunnel layer 110, doping depth of the nitrogen (N) atoms in the tunnel layer 110, and thickness of the tunnel layer 110, etc, are changed by conditions such as a flow rate ratio of the O₂ gas to the N₂ gas, the electric power of plasma, and the temperature of the silicon substrate 100, and so forth. By adjusting them, desired doses, doping depth, and thickness can be obtained.

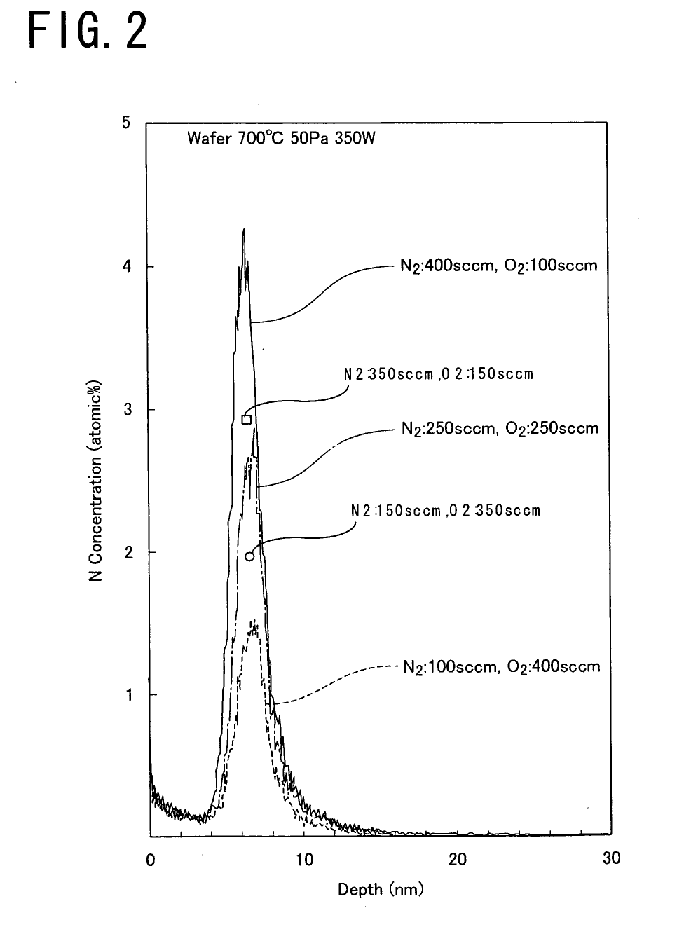

FIG. 2 illustrates the depth profile (composition analysis result in the thickness direction) of the tunnel layer 110, when the ratio of the supply flow rate of the O₂ gas to the supply flow rate of the N₂ gas is changed. The depth from the surface of the tunnel layer is indicated on the horizontal axis in the figure, and the ratio (%) of the number of atoms of the nitrogen (N) elements to the total number of atoms is indicated on the vertical axis. According to FIG. 2, it is found that the doses of the nitrogen (N) atoms are increased, by increasing the supply flow rate of the N₂ gas with respect to the supply flow rate of the O₂ gas (namely, by sequentially changing the supply flow rate of the O₂ gas the supply flow rate of the N₂ gas, so as to be 400 sccm 100 sccm, 250 sccm:250 sccm, and 100 sccm: 400 sccm). In addition, even in any one of the aforementioned flow rate ratio, it is found that the nitrogen (N) atoms are doped into a prescribed depth (in the vicinity of 6 nm in this embodiment) of the tunnel layer 110 so as to be unevenly distributed. Note that the other conditions are the same as those of the case of FIG. 1.

In addition, the ratio of the nitrogen of a nitrogen peak layer is required to be at least 1.5% or more, as the other condition. This is because in a case of under 1.5%, a bonding level of each element (silicon, oxygen, nitrogen) in the interface becomes low and a defect occurs. In this embodiment, the flow rate of N₂ is set at 100 sccm, and the flow rate of O₂ is set at 400 sccm, to obtain 1.5% of the nitrogen ratio. The nitrogen ratio is also preferably set at 4.5% or less. This is because when nitrogen components of 4.5% or more are contained, the nitrogen components are saturated, to restrain pass of the charge. In the present invention, in order to set the nitrogen ratio at 4.5%, the flow rate of N₂ is set at 400 sccm, and the flow rate of O₂ is set at 100 sccm. More preferably, the nitrogen ratio is set at 2% or more and 3% or less. This is the ratio required as the standard value of the leakage current of the tunnel insulating film for retaining the charge stored in the charge conservation layer at the time of forming the device. According to the present invention, in order to obtain 2.0%, the flow rate of N₂ is set at 150 sccm, and the flow rate of O₂ is set at 350 sccm. Also, according to this embodiment, in order to obtain 3.0%, the flow rate of N₂ is set at 350 sccm and the flow rate of O₂ is set at 150 sccm. Note that in the above description, a case of using the O₂ gas and N₂ gas is taken as an example. However, the present invention is not limited thereto, and it is also possible by the number of atoms corresponding to the aforementioned ratio of the flow rate, and similar processing is possible even by the mixed gas of the nitrogen and oxygen.

As described above, the nitridation layer 150 is formed. By this nitridation layer 150, the bonding level between the silicon substrate 100 and the tunnel oxide layer in the interface is increased, and the leakage current from the tunnel layer 110 can be restrained.

### (Exhaust of Residual Gas)

When the formation of the tunnel layer 110 is finished, electric power supply to the cylindrical electrode 215 and gas supply into the processing chamber 201 are stopped. Then, the residual gas in the processing chamber 201 is exhausted by using the exhaust tube 231. Then, the susceptor 217 is descended down to a carrying position of the silicon substrate 100, so that the silicon substrate 100 is supported on the wafer lifting pins 266 protruded from the surface of the susceptor 217. Then, the gate valve 244 is opened and the silicon substrate 100 is unloaded to the outside the processing chamber 201 by using a carrying means not shown. Thus, the method for manufacturing the semiconductor device according to this embodiment is finished.

### (3) Advantages of this Embodiment

According to this embodiment, one or a plurality of advantages as will be described hereunder are exhibited.

According to this embodiment, the O₂ gas and the N₂ gas supplied into the processing chamber 201 are activated by plasma and the silicon substrate 100 is exposed to the activated gas. Therefore, the tunnel layer 110 can be formed by heating the surface of the silicon substrate 100 at a temperature of 675° C. or more and under 900° C., for example at about 700° C. and 800° C. By limiting the surface temperature of the silicon substrate 100 at the time of forming the tunnel layer 110 in this range, controllability of the diffusion of the impurities in the silicon substrate 100 can be improved and microfabrication of the semiconductor device can be realized. In addition, the degradation of the circuit characteristics can be restrained and the performance of the semiconductor device can be improved.

Further, according to this embodiment, not only the O₂ gas but also the N₂ gas can be simultaneously supplied into the processing chamber 201. Namely, the mixed gas of the O₂ gas and the N₂ gas can be supplied into the processing chamber 201. Thus, by supplying the mixed gas of the O₂ gas and the N₂ gas into the processing chamber 201, the nitrogen (N) atoms are doped into a prescribed depth of the tunnel layer 110 composed of SiO₂ at a concentration of several %, to alleviate the strain of the interface between the silicon substrate 100 and the tunnel layer 110, and the tunnel layer 110 with high reliability can be obtained.

In addition, according to this embodiment, an unstable level in the tunnel layer 110 is not required to be terminated by the hydrogen (H) atoms (dangling bonds are recombined). Namely, even if a long term electrical stress is added to the tunnel layer 110, the phenomenon of gradual increase of the leakage current caused by desorption of the hydrogen atoms is not allowed to occur, and the tunnel layer 110 with high reliability can be obtained.

FIG. 3 shows a graph for comparing a measured value of the leakage current of the tunnel layer 110 according to this embodiment and a measured value of the leakage current of the tunnel layer formed by other method. The voltage value (unit V) added to the formed film is indicated on the horizontal axis, and a leakage current density (A/cm²) in the formed film is indicated on the vertical axis in the figure. In the figure, ◯ indicates the measured value of the tunnel layer 110 formed, with the surface temperature of the silicon substrate 100 set at 485° C., and □ indicates the measured value of the tunnel layer 110 formed, with the surface temperature of the silicon substrate 100 set at 675° C., and ⋄ indicates the measured value of the tunnel layer 110 formed, with the surface temperature of the silicon substrate 100 set at 800° C. In the symbols such as ◯, □, ⋄, the conditions other than the surface temperature of the silicon substrate 100 are approximately the same as those of the aforementioned embodiment. Also, Δ indicates the measured value of the SiO₂ film (SiO₂ film by wet oxidation) fabricated by exposing the surface of the silicon substrate to H₂O gas (vapor), with the surface temperature of the silicon substrate set at 800° C. In addition, ▴ indicates the measured value of the SiO₂ film (SiO₂ film caused by thermal radical oxidation) fabricated by exposing the surface of the silicon substrate to active species excited by heat, with the surface temperature of the silicon substrate set at 800° C. In all of the symbols such as ◯, □, ⋄, Δ, ▴, the thickness of the formed SiO₂ film is about 5 nm.

When the symbols ◯, □, ⋄ are compared, it is found that as the surface temperature of the silicon substrate 100 is increased, the leakage current density is reduced. Then, it is found that the leakage current density can be sufficiently reduced in the case of the symbols □ (675° C.) and ⋄ (800° C.), with the surface temperature of the silicon substrate 100 set in a range of 600° C. or more and under 900° C. When A (SiO₂ film by wet oxidation) and ▴ (SiO₂ film by thermal radical oxidation), and □ and ⋄ are compared, it is found that □ (675° C.) is a value capable of reducing the leakage current, more than Δ and ▴ in at least each of a low voltage region (2.5V or less) and a high voltage region (5V or more). Also, it is found that ⋄ (800° C.) is a value capable of reducing the leakage current more than Δ and ▴ in approximately all voltage values (8V or less). (0052)

### OTHER EMBODIMENT OF THE PRESENT INVENTION

An embodiment of the present invention has been described above. However, the present invention is not limited to the aforementioned embodiment and can be executed by suitable modification.

For example, in the aforementioned embodiment, explanation has been given for a case such as being executed by using the MMT apparatus. However, the present invention is not limited thereto, and can be executed by using other apparatus, for example by using ICP (Inductively Coupled Plasma) and ECR (Electron Cyclotron Resonance) apparatus.

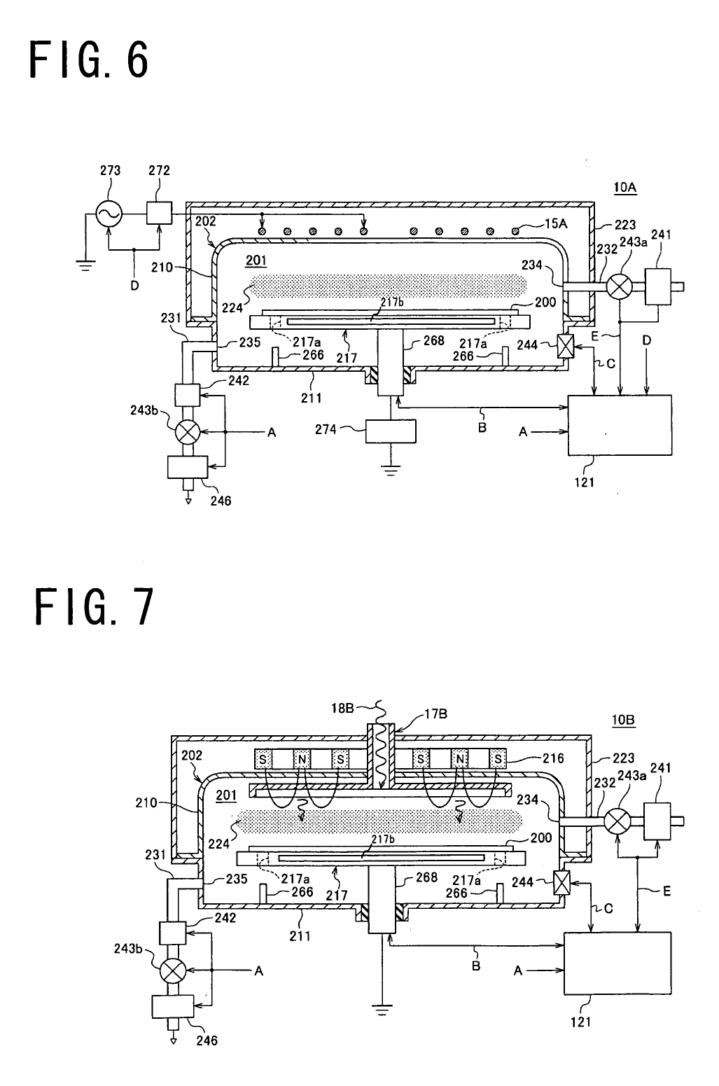

FIG. 6 illustrates an ICP plasma processing apparatus, being the substrate processing apparatus according to a second embodiment of the present invention. The same signs and numerals are assigned to constituent elements having similar function as the function of the first embodiment and detailed description of the structure according to this embodiment is omitted. An ICP plasma processing apparatus 10A according to this embodiment includes an induction coil 15A, being a plasma generating part, for generating plasma by supplying power, and the induction coil 15A is laid on the outer side of a ceiling wall of the processing vessel 202. In this embodiment also, the mixed gas of the nitrogen gas and rare gas is supplied to the processing vessel 202 through the gas outlet port 234 from the gas supply tube 232. In addition, almost simultaneously with the gas supply, when the high frequency power is flown to the induction coil 15A, being the plasma generating part, the electric field is generated by the electromagnetic induction. The supplied gas is plasmatized, with this electric field as energy, and nitrogen active species are generated by this plasma, to form the tunnel layer on the wafer 100.

FIG. 7 illustrates the ECR plasma processing apparatus, being the substrate processing apparatus according to a third embodiment of the present invention. The same signs and numerals are assigned to the constituent elements having the similar function as the function of the aforementioned embodiment and the detailed description of the structure according to this embodiment is omitted. An ECR plasma processing apparatus 10B according to this embodiment includes a microwave introducing tube 17B, being the plasma generating part, for generating plasma by supplying microwave. In this embodiment also, the mixed gas of the nitrogen gas and the rare gas is supplied to the processing vessel 202 from the gas supply tube 232 through the gas outlet port 234. Also, almost simultaneously with the gas supply, the microwave 18B is introduced to the microwave introducing tube 17B, being the plasma generating part, and thereafter the microwave 18B is emitted to the processing chamber 201. The supplied gas is plasmatized by this microwave 18B, and by this plasma, the nitrogen active species are generated, and the tunnel layer is formed on the wafer 100.

### PREFERRED ASPECTS OF THE PRESENT INVENTION

Preferred aspects of the present invention will be described hereunder.

A first aspect provides a method for manufacturing a semiconductor device including the steps of: supplying gas containing oxygen atoms and nitrogen atoms into a processing chamber; activating the gas containing the oxygen atoms and the nitrogen atoms by plasma; and applying processing to a silicon substrate having a surface temperature of 675° C. or more by the plasma and forming a silicon dioxide film containing nitrogen.

A second aspect provides the method for manufacturing the semiconductor device according to the first aspect, wherein the surface temperature of the silicon substrate is 675° C. or more and under 900° C.

A third aspect provides a method for manufacturing a semiconductor device including the steps of: supplying gas into a processing chamber, with a ratio of flow rates of oxygen and nitrogen set in a range of 1:4 to 4:1; activating the gas containing oxygen atoms and nitrogen atoms by plasma; and applying processing to a silicon substrate by the plasma and forming a silicon dioxide film containing the nitrogen.

A fourth aspect provides the method for manufacturing the semiconductor device according to the third aspect, wherein the ratio of the flow rate of the oxygen and the nitrogen is 3:7 to 7:3.

A fifth aspect provides the method for manufacturing the semiconductor device according to the third aspect to the fourth aspect, wherein a nitrogen concentration in the interface between the silicon oxide film and the silicon substrate is 1.5 to 4.5%.

A sixth aspect provides the method for manufacturing the semiconductor device according to the third aspect to the fourth aspect, wherein a nitrogen concentration in the interface between the silicon oxide film and the silicon substrate is 2.0 to 3.0%.

There is provided a substrate processing apparatus, including: an oxygen gas supply part configured to supply gas containing oxygen atoms; a nitrogen gas supply part configured to supply gas containing nitrogen atoms; a plasma generating part configured to activate the supplied gas; a susceptor configured to place a silicon substrate thereon; a heater incorporated in the susceptor; and a controller configured to supply the gas containing the oxygen atoms and the nitrogen atoms into a processing chamber, then activate the gas containing the oxygen atoms and the nitrogen atoms by plasma, and apply processing to a silicon substrate having a surface temperature of 675° C. or more by the plasma.

1. A method for manufacturing a semiconductor device, comprising the steps of:
supplying gas containing oxygen atoms and nitrogen atoms into a processing chamber;
activating the gas containing the oxygen atoms and the nitrogen atoms by plasma; and
applying processing to a silicon substrate having a surface temperature of 675° C. or more by the plasma and forming a silicon dioxide film containing nitrogen.

2. The method for manufacturing the semiconductor device according to claim 1, wherein the surface temperature of the silicon substrate is 675° C. or more and under 900° C.

3. A method for manufacturing a semiconductor device, comprising the steps of:
supplying gas into a processing chamber, with a ratio of flow rates of oxygen and nitrogen set in a range of 1:4 to 4:1;
activating the gas containing oxygen atoms and nitrogen atoms by plasma; and
applying processing to a silicon substrate by the plasma and forming a silicon dioxide film containing the nitrogen.

4. The method for manufacturing the semiconductor device according to claim 3, wherein the ratio of the flow rate of the oxygen and the nitrogen is 3:7 to 7:3.

5. The method for manufacturing the semiconductor device according to claim 3, wherein a nitrogen concentration in an interface between the silicon oxide film and the silicon substrate is 1.5 to 4.5%.

6. The method for manufacturing the semiconductor device according to claim 3, wherein a nitrogen concentration in an interface between the silicon oxide film and the silicon substrate is 2.0 to 3.0%.

7. A substrate processing apparatus, comprising: an oxygen gas supply part configured to supply gas containing oxygen atoms;
a nitrogen gas supply part configured to supply gas containing nitrogen atoms;
a plasma generating part configured to activate the supplied gas;
a susceptor configured to place a silicon substrate thereon;
a heater incorporated in the susceptor; and
a controller configured to supply the gas containing the oxygen atoms and the nitrogen atoms into a processing chamber, then activate the gas containing the oxygen atoms and the nitrogen atoms by plasma, and apply processing to a silicon substrate having a surface temperature of 675° C. or more by the plasma.

8. The method for manufacturing the semiconductor device according to claim 4, wherein a nitrogen concentration in an interface between the silicon oxide film and the silicon substrate is 1.5 to 4.5%.

9. The method for manufacturing the semiconductor device according to claim 4, wherein a nitrogen concentration in an interface between the silicon oxide film and the silicon substrate is 2.0 to 3.0%.
